(19) United States
(12) Patent Application Publication
(10) Pub. No.: US 2018/0366576 A1
(43) Pub. Date: Dec. 20, 2018

(54) SEMICONDUCTOR DEVICE AND POWER CONVERSION CIRCUIT

(71) Applicant: UBIQ Semiconductor Corp., Zhubei City (TW)

(72) Inventors: Nobuyuki SHIRAI, Gunma-ken (JP); Nobuyoshi MATSUURA, Gunma-ken (JP)

(21) Appl. No.: 15/995,164

(22) Filed: Jun. 1, 2018

(30) Foreign Application Priority Data
Jun. 19, 2017 (JP) 2017-119932

(51) Int. Cl. H01L 29/78; H01L 29/417; H01L 29/06; H01L 23/64

(52) U.S. Cl. CPC H01L 29/7813; H01L 29/41741; H01L 23/647; H01L 23/645; H01L 29/0653

(57) ABSTRACT

A semiconductor device is disclosed. The semiconductor device includes a semiconductor substrate, a gate electrode, a drain electrode and a source electrode. The gate electrode, the drain electrode and the source electrode are formed on the semiconductor substrate. An area of the source electrode is larger than an area of the gate electrode and the area of the drain electrode. A part of the source electrode has a convex shape and disposed between the gate electrode and the drain electrode. The semiconductor device of the invention can maintain various switching characteristics and enable high-speed switching.

### BACKGROUND OF THE INVENTION

### 1. Field of the Invention

The invention relates to a semiconductor device; in particular, to a semiconductor device and a power conversion circuit having a gate electrode, a source electrode and a drain electrode.

### 2. Description of the Prior Art

With the trend toward miniaturization and thinning of mobile electronic devices, package substrates and power conversion semiconductor devices built into the mobile electronic devices (e.g., smart phones or tablet computers) are bound to be miniaturized and thinned.

The prior art is a lead frame type package in which a lead exposed is used from the side of the sealing resin sealing the semiconductor element to the other side. However, when the lead frame type package is mounted on a package substrate using a solder, since solder is formed on a side of the lead frame type package, the lead frame type package needs a large packaging area, thereby miniaturization and thinning of package substrates and mobile electronic devices are hindered.

In order to solve the above-mentioned problems, the industry has developed a chip size package (CSP), which can be surface-bonded by the electrode fusion solder formed below, so that the package area can be reduced and miniaturization of the package substrate and the mobile electronic device can be promoted.

Prior art 1 (U.S. Pat. No. 7,781,894), Prior art 2 (U.S. Pat. No. 8,148,233), and Prior art 3 (U.S. Pat. No. 7,049,194) describe a technology forming the electrodes of the MOSFET on the semiconductor substrate. For example, FIG. 2 of Prior art 1 and related descriptions disclose a semiconductor device in which the gate electrode, the source electrode and the drain electrode are formed on the semiconductor substrate. When the semiconductor device having such structure is mounted on the package substrate, the semiconductor device is coupled to the electrodes and the conductive path on the package substrate through the solder that is welded to each of the gate electrode, the source electrode and the drain electrode. In this way, the area required of packaging the MOSFET can be reduced.

As to Prior art 4 (U.S. Pat. No. 6,653,740), as well as Prior arts 1˜3, it describes a structure in which the gate electrode, the source electrode and the drain electrode are formed on the semiconductor substrate, and solder balls are welded to these electrodes.

Prior art 1: U.S. Pat. No. 7,781,894

Prior art 2: U.S. Pat. No. 8,148,233

Prior art 3: U.S. Pat. No. 7,049,194

Prior art 4: U.S. Pat. No. 6,653,740

### SUMMARY OF THE INVENTION

However, in the MOSFET described in the above-mentioned prior arts, since the gate electrode, the source electrode and the drain electrode of the MOSFET have substantially the same size, it is difficult to significantly reduce the connection resistance.

Furthermore, in the above-mentioned patent documents, since the gate electrode, the source electrode and the drain electrode are disposed at all corners on the semiconductor substrate, if a MOSFET is disposed on the conductive path of the package substrate, for example, a DC-DC converter is disposed on the package substrate using the MOSFET or the like, in order to make the conductive path coupling the source electrode conductive, multiple layers of conductive paths must be formed on the package substrate. However, this will increase unnecessary inductance on the conductive path of the package substrate side and impede high-speed switching, resulting in huge power consumption and low power conversion efficiency.

In addition, if the areas of the gate electrode, the source electrode and the drain electrode are increased, the amount of solder used in the packaging process will increase, and it will become difficult to stably package the semiconductor device.

In view of the above-mentioned problems, the invention provides a semiconductor device and a power conversion circuit which can not only maintain various characteristics during switching, but also perform high-speed switching.

An embodiment of the invention is a semiconductor device. In this embodiment, the semiconductor device includes:

a semiconductor substrate having a first surface and a second surface opposite to each other, wherein a gate region, a drain region and a source region is formed on the semiconductor substrate;

a gate electrode, disposed on the first surface of the semiconductor substrate and coupled to the gate region;

a drain electrode, disposed on the first surface of the semiconductor substrate and coupled to the drain region;

a source electrode, disposed on the first surface of the semiconductor substrate and coupled to the source region, wherein an area of the source electrode is larger than an area of the gate electrode and an area of the drain electrode; and

a covering insulation layer, disposed on the first surface of the semiconductor substrate and at least partially covering the gate electrode, the drain electrode and the source electrode,

wherein a gate exposed portion of the gate electrode is exposed from the covering insulation layer; a source exposed portion of the source electrode is exposed from the covering insulation layer; a drain exposed portion of the drain electrode is exposed from the covering insulation layer; a part of the source electrode is disposed between the gate electrode and the drain electrode; the source exposed portion is disposed between the gate exposed portion and the drain exposed portion.

Therefore, by disposing a part of the source electrode between the drain electrode and the gate electrode, the connection resistance when the semiconductor device is mounted on the semiconductor substrate can be reduced, and the diffusion resistance of the MOSFET can be also reduced. Therefore, the area of the source electrode used as the ground electrode connecting to the conductive path disposed on the substrate can be increased to reduce the noise generated on the circuit in which the semiconductor device is packaged. In addition, by disposing the source exposed portion between the gate exposed portion and the drain exposed portion, the connection resistance of mounting the semiconductor substrate can also be reduced. Furthermore, when the solder is soldered and adhered to the source exposed portion, the gate exposed portion and the drain exposed portion, it can also reduce the accidental displacement of the semiconductor device.

In an embodiment of the invention, the gate exposed portion, the source exposed portion and the drain exposed portion are disposed relative to a side of the semiconductor substrate and the gate exposed portion, the source exposed portion and the drain exposed portion are line symmetrical with respect to a base line.

Therefore, by arranging the gate exposed portion, the source exposed portion and the drain exposed portion in line symmetry, in the step of packaging the semiconductor device, solder can be uniformly welded to those exposed portions and the semiconductor device can become more stable during packaging.

In an embodiment of the invention, the source exposed portion is line symmetrical with respect to the base line.

Therefore, in the package state, the connection resistance can be reduced by forming a larger source exposed portion. In addition, when the semiconductor device is packaged, although more solder may be used on the larger source exposed portion to affect the stability when packaging, since the source exposed portion exhibits line symmetry, the stability of the semiconductor device when packaging can be enhanced.

In an embodiment of the invention, the semiconductor device further includes:

a wiring, coupled to the drain region or the gate region, wherein the part of the source electrode between the gate electrode and the drain electrode is disposed inside separated from the wiring, the part of the source electrode is separated from a side of the semiconductor substrate by a first distance, and another part of the source electrode, the drain exposed portion and the gate exposed portion are separated from the side of the semiconductor substrate by a second distance equal to the first distance.

Therefore, by arranging the source exposed portion located between the drain exposed portion and the gate exposed portion on the outside and determining the positions of the other exposed portions based on the position of the source exposed portion, those exposed portions can be uniformly arranged on the outside. Therefore, when the semiconductor device is packaged in the reflow step, the packaging can be uniformly performed.

In an embodiment of the invention, the semiconductor device further includes:

a gate wiring, disposed around the source electrode and coupled to the gate region and the gate electrode.

Therefore, not only the gate resistance can be reduced, but also the semiconductor device can be switched at high speed, and the power supply system efficiency of the semiconductor device can be improved.

Another embodiment of the invention is power conversion circuit. In this embodiment, the power conversion circuit includes a semiconductor device and a package substrate. The package substrate has a conductive path. The semiconductor device is packaged on the conductive path.

Therefore, in the power conversion, since the semiconductor device can stably perform the switching operation, the power conversion efficiency can be effectively enhanced.

The advantage and spirit of the invention may be understood by the following detailed descriptions together with the appended drawings.

### BRIEF DESCRIPTION OF THE APPENDED DRAWINGS

FIG. 1A and FIG. 1B illustrate the semiconductor device in an embodiment of the invention, wherein FIG. 1A is a plan view of the semiconductor device and FIG. 1B is a plan view of the semiconductor device packaged on the package substrate.

FIG. 2A and FIG. 2B illustrate the semiconductor device in another embodiment of the invention, wherein FIG. 2A is a cross-sectional diagram of the source electrode formed in the semiconductor device and FIG. 2B is a cross-sectional diagram of the drain electrode formed in the semiconductor device.

FIG. 3A and FIG. 3B illustrate plan views of the semiconductor device in another embodiment of the invention respectively.

FIG. 4A and FIG. 4B illustrate plan views of the semiconductor device in another embodiment of the invention respectively.

FIG. 5A and FIG. 5B illustrate the semiconductor device in another embodiment of the invention, wherein FIG. 5A is a plan view of the semiconductor device and FIG. 5B is a partially enlarged plan view of FIG. 5A.

FIG. 6A and FIG. 6B illustrate plan views of the semiconductor device in another embodiment of the invention respectively.

### DETAILED DESCRIPTION OF THE INVENTION

Exemplary embodiments of the semiconductor device 10 in the present invention are referenced in detail now, and examples of the exemplary embodiments are illustrated in the drawings. Further, the same or similar reference numerals of the elements/components in the drawings and the detailed description of the invention are used on behalf of the same or similar parts.

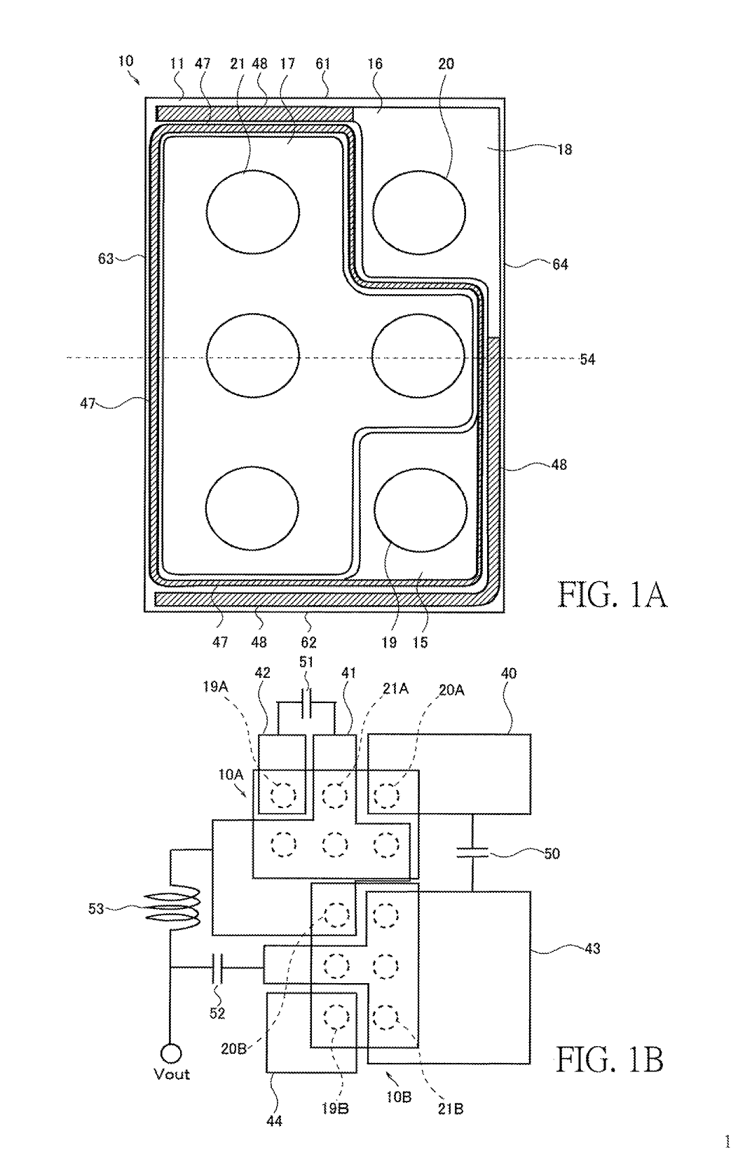

Please refer to FIG. 1A and FIG. 1B. FIG. 1A is a plan view of the semiconductor device 10 and FIG. 1B is a plan view of the semiconductor device 10 packaged on the conductive path of the package substrate 11.

As shown in FIG. 1A, the semiconductor device 10 is a metal-oxide-semiconductor field-effect transistor (MOSFET), and the MOSFET has a gate region, a source region and a drain region formed in the semiconductor substrate 11. Specifically, the semiconductor device 10 includes the semiconductor substrate 11, and the gate electrode 15, the drain electrode 16 and the source electrode 17 are formed on the semiconductor substrate 11. The gate electrode 15, the drain electrode 16 and the source electrode 17 are coupled to the gate region, the drain region and the source region formed in the semiconductor substrate 11 respectively.

The semiconductor substrate 11 can be made of a semiconductor material such as silicon. If viewed planarly, the semiconductor substrate 11 exhibits a rectangular shape. The semiconductor substrate 11 has a first surface and a second surface (not shown) facing each other, wherein the first surface is located above the paper surface, and the second surface is opposite to the first surface. In addition, if viewed planarly, the semiconductor substrate 11 has four sides including an upper side 61, a lower side 62, a left side 63 and a right side 64.

The semiconductor substrate 11 is covered by a cover insulation layer 18 made of synthetic resin. Similarly, the gate electrode 15, the drain electrode 16 and the source electrode 17 are also covered by the cover insulation layer 18. Portions of the gate electrode 15, the drain electrode 16 and the source electrode 17 exposed from the substantially circular opening of the cover insulation layer 18 are called a gate exposed portion 19, a drain exposed portion 20 and a source exposed portion 21 respectively.

The gate electrode 15 is formed near the lower right corner of the semiconductor substrate 11 and has a substantially rectangular shape. The gate exposed portion 19 is formed substantially in the central region of the gate electrode 15.

The drain electrode 16 is formed near the upper right corner of the semiconductor substrate 11 and has a substantially rectangular shape. The drain exposed portion 20 is formed substantially in the central region of the drain electrode 16.

The gate electrode 15 and the drain electrode 16 are arranged along the right side 64 of the semiconductor substrate 11, and the gate exposed portion 19 and the drain exposed portion 20 are also arranged along the right side 64 of the semiconductor substrate 11.

The area of the source electrode 17 is larger than the area of the gate electrode 15 and the area of the drain electrode 16. By increasing the area of the source electrode 17, not only the diffusion resistance of the MOSFET can be reduced, but also the connection resistance when the semiconductor device 10 is packaged on the conductive path of the package substrate can be reduced.

The source electrode 17 is formed by extending from the side upper 61 of the semiconductor substrate 11 to the lower side 62 of the semiconductor substrate 11 along the left side 63 of the semiconductor substrate 11. In addition, a part of the source electrode 17 protrudes toward the right side 64 of the semiconductor substrate 11 and is located between the drain electrode 16 and the gate electrode 15. In other words, if viewed planarly, the shape of the source electrode 17 is a rectangle that protrudes to the right side in the middle between the upper side and the lower side of the semiconductor substrate 11 to increase the area of the source electrode 17 as much as possible and help to simplify the structure of the conductive path on the package substrate side as will be described later.

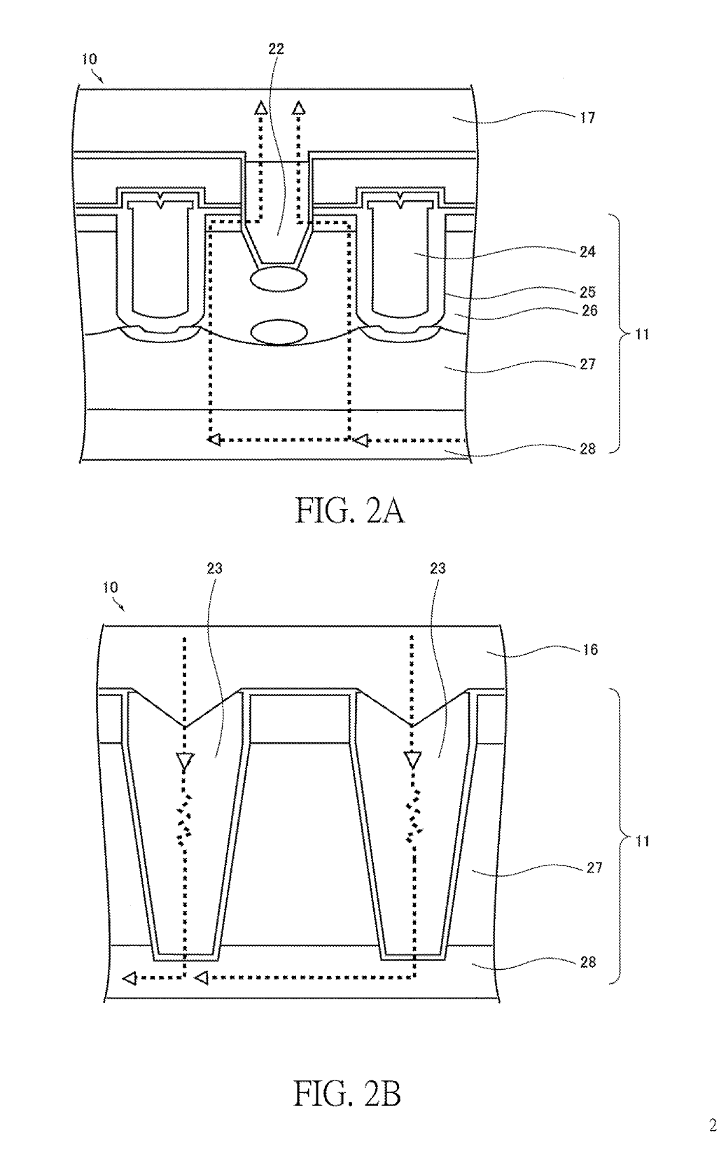

The gate wiring 47 is coupled to the gate electrode 15 and the gate embedded electrode 24 embedded in the semiconductor substrate 11 (see FIG. 2A) and is disposed around the source electrode 17. By forming the gate wiring 47 coupled to the gate electrode 15 and surrounding the source electrode 17, not only the gate resistance can be reduced, but also the semiconductor device 10 can be operated at high speed, thereby the efficiency of the electrode converting circuit of the semiconductor device 10 can be increased.

In addition, a drain wiring 48 is formed at a peripheral edge portion of the semiconductor substrate 11, and the drain wiring 48 is coupled to the drain electrode 16 and the drain region of the semiconductor substrate 11. As described above, the drain electrode 16 is formed near the upper right corner of the semiconductor substrate 11. The drain wire 48 extends from the upper left corner of the drain electrode 16 to the left end of the upper side 61 along the upper side 61. The drain wire 48 also extends from the lower right corner of the drain electrode 16 to the left end of the lower side 62 along the right side 64 and the lower side 62.

As described above, although the gate electrode 15, the drain electrode 16 and the source electrode 17 are formed on the semiconductor substrate 11, those electrodes have symmetrical positions and shapes. In this embodiment, a base line 54 is defined on the semiconductor substrate 11, and the base line 54 is located at the center of the semiconductor substrate 11 on the top and bottom direction and parallel to the upper side 61 of the semiconductor substrate 11. The gate electrode 15, the drain electrode 16 and the source electrode 17 will be line symmetrical with respect to the base line 54. Specifically, the gate electrode 15 and the drain electrode 16 are line symmetrical with respect to the base line 54, and the base line 54 is also located at the center of the source electrode 17 on the top and bottom direction. Therefore, the source electrode 17 is also line symmetrical with respect to the base line 54. In addition, the shapes of the gate electrode 15, the drain electrode 16 and the source electrode 17 are also line symmetrical with respect to the base line 54, thereby the resistances of the gate electrode 15, the drain electrode 16 and the source electrode 17 can be reduced.

The gate exposed portion 19, the drain exposed portion 20 and the source exposed portion 21 also have symmetrical positions and shapes. In this embodiment, the positions and shapes of the gate exposed portion 19, the drain exposed portion 20 and the source exposed portion 21 are all line symmetrical with respect to the base line 54. By doing so, when the semiconductor device 10 is welded by the solder, the gate exposed portion 19, the drain exposed portion 20 and the source exposed portion 21 which are symmetrically arranged can make the solder uniformly attached to the gate exposed portion 19, the drain exposed portion 20 and the source exposed portion 21. Therefore, when the surface of the semiconductor device 10 is adhered to the package substrate through subsequent steps such as reflow, it is possible to effectively prevent the semiconductor device 10 from being moved, rotated or tilted due to factors such as the surface tension of the liquid solder.

A plurality of source exposed portions 21 may be formed on the source electrode 17. In this embodiment, three source exposed portions 21 are formed along the vertical direction on the left side of the source electrode 17, and one source exposed portion 21 is formed on the right-side protruding portion of the source electrode 17.

Please refer to FIG. 1B. FIG. 1B illustrates a plan view of the semiconductor device 10A˜10B packaged on the package substrate 11. The conductive paths 40˜44 can be formed on a package substrate (not shown). For example, the conductive film can be formed on the package substrate (e.g., a glass epoxy substrate) and patterned into a predetermined shape to form a single-layer conductive path 40˜44. The semiconductor devices 10A˜10B can form the output stage of the DC-DC converter (the power conversion circuit). For example, the semiconductor device 10A forms an upper bridge switching element and the semiconductor device 10B forms a lower bridge switching element.

The semiconductor devices 10A˜10B packaged on the conductive paths 40˜44 have the same structure as the semiconductor device 10 described above. The semiconductor devices 10A˜10B are coupled to the conductive paths 40˜44 by being fixedly bonded to the conductive paths 40˜44 through the solder welded to the gate exposed portion 19, the drain exposed portion 20 and the source exposed portion 21.

A gate exposed portion 19A, a drain exposed portion 20A and a source exposed portion 21A are formed under the semiconductor device 10A. The gate exposed portion 19A is coupled to the conductive path 42; the drain exposed portion 20A is coupled to the conductive path 40; source exposed portions 21A are coupled to the conductive path 41.

A gate exposed portion 19B, a drain exposed portion 20B and a source exposed portion 21B are formed under the semiconductor device 10B. The gate exposed portion 19B is coupled to the conductive path 44; the drain exposed portion 20B is coupled to the conductive path 41; source exposed portions 21B are coupled to the conductive path 43.

The source exposed portion 21A of the semiconductor device 10A and the drain exposed portion 20B of the semiconductor device 10B are both coupled to the same conductive path 41, that is to say, the source of the semiconductor device 10A and the drain of the semiconductor device 10B are coupled to each other through the conductive path 41.

In addition, if viewed planarly, the longitudinal direction of the semiconductor device 10A extends along the lateral direction, and the longitudinal direction of the semiconductor device 10B extends along the longitudinal direction. Therefore, the longitudinal direction of the semiconductor device 10A and the longitudinal direction of the semiconductor device 10B are mutually orthogonal.

The conductive path 40 is coupled to a power supply voltage and the conductive path 43 is coupled to a ground voltage. The capacitor 50 is coupled between the conductive path 40 and the conductive path 43.

The conductive path 42 and the conductive path 44 are coupled to a control device (not shown) for respectively transmitting the control signals output by the control device to the gate exposed portions 19A˜19B of the semiconductor devices 10A˜10B to control the gate electrodes of the semiconductor devices 10A˜10B.

The conductive path 42 and the conductive path 41 are coupled through a boost capacitor 51. The conductive path 41 and the conductive path 43 are coupled through the inductor 53 and the capacitor 52 coupled in series, and an output voltage Vout is obtained between the inductor 53 and the capacitor 52.

When the above-mentioned DC-DC converter starts operating, at first, a DC power supply voltage is inputted to the conductive path 40 and a ground voltage is inputted to the conductive path 43. In addition, a control signal is inputted to the gate exposed portion 19A of the semiconductor device 10A through the conductive path 42 and the control signal is inputted to the gate exposed portion 19B of the semiconductor device 10B through the conductive path 44, so that the semiconductor device 10A used as the lower bridge switching element and the semiconductor device 10B used as the lower bridge switching element are controlled by the control signal to be switched at a predetermined speed. When the semiconductor device 10A used as the upper bridge switching element is turned on, energy will be stored in the inductor 53; when the semiconductor device 10B used as the lower bridge switching element is turned on, the energy stored in the inductor 53 will be outputted.

By doing so, by operating the DC-DC converter, the input voltage of, for example, about 19 volts can be buck to about 1 volt, and the above-mentioned circuit can be also called a buck converter circuit.

From the foregoing, it can be found that in the semiconductor device 10A, since the source exposed portion 21A is located between the gate exposed portion 19A and the drain exposed portion 20A, it is helpful to guide the conductive path 41 to the outside. That is to say, the package substrate in which the semiconductor device 10A is packaged does not need to adopt a multi-layer structure, and a single-layer package substrate can be used. Even when the semiconductor device 10A performs switching at high speed, the noise accompanying the switching of the switches can be effectively suppressed. In addition, the wiring inductance and the peak voltage of the package substrate can be also reduced, and the effects of high-speed switching, losses reducing and system performance enhancing can be achieved.

Please refer to FIG. 2A and FIG. 2B. FIG. 2A is a cross-sectional diagram of the source electrode 17 formed in the semiconductor device 10 and FIG. 2B is a cross-sectional diagram of the drain electrode 16 formed in the semiconductor device 10. The dashed lines in FIG. 2A and FIG. 2B are used to indicate the current flowing paths.

As shown in FIG. 2A, a body region 26, an epitaxial layer 27 and a substrate layer 28 are formed in the semiconductor substrate 11 from above and below. A trench is formed in the body region 26. A gate oxide film 25 is formed in the trench and a gate embedded electrode 24 is formed in the gate oxide film 25. The gate embedded electrode 24 can be coupled to the gate electrode 15 formed on the semiconductor substrate 11 through the above-mentioned gate wiring 47.

A plug 22 is formed by embedding a metal (e.g., titanium) into the semiconductor substrate 11 to partially penetrate the body region 26. The lower end of the plug 22 reaches the body region 26 and the upper end of the plug 22 is coupled to the source electrode 17. The resistance at startup can be reduced through the formation of the plug 22.

When a control signal is inputted to the gate embedded electrode 24 to start the operation of the semiconductor device 10, a channel will be formed around the gate oxide film 25, and the current can flow through the substrate layer 28, the epitaxial layer 27, the body region 26, the plug 22 to the source electrode 17 in order, as shown by the dashed line in FIG. 2A.

As shown in FIG. 2B, a plug 23 is formed on the semiconductor substrate 11 so as to partially penetrate the epitaxial layer 27. The lower end of the plug 23 reaches the substrate layer 28 and the upper end of the plug 23 is coupled to the drain electrode 16. As described above, when the operation of the semiconductor device 10 is started, the current will flow through the drain electrode 16 and the plug 23 to the substrate layer 28 in order, as shown by the dashed line in FIG. 2B. Then, the current will flow from the substrate layer 28 to the source electrode 17 as shown in FIG. 2A.

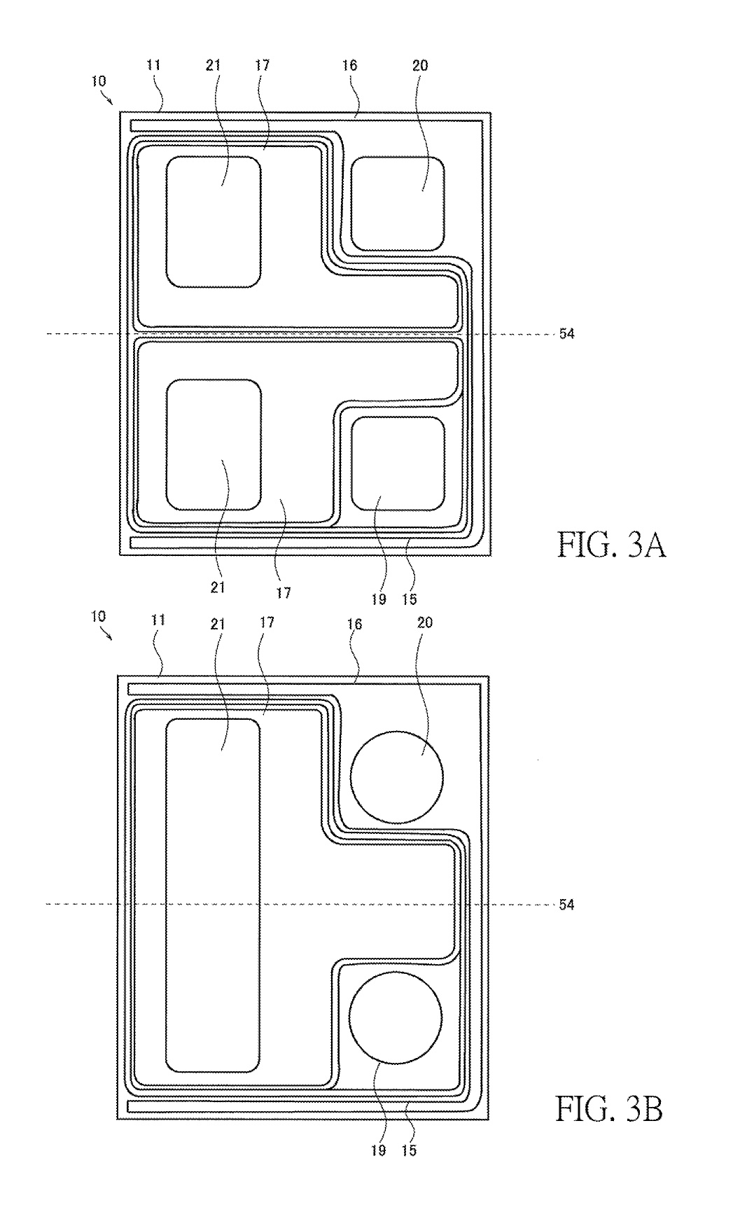

Please refer to FIG. 3A and FIG. 3B. FIG. 3A and FIG. 3B illustrate plan views of the semiconductor device in another embodiment of the invention. The structure of the semiconductor device 10 illustrated in FIG. 3A and FIG. 3B is basically the same as that of FIG. 1, and only the shapes of the exposed portions are different.

As shown in FIG. 3A, the gate exposed portion 19, the drain exposed portion 20 and the source exposed portion 21 are substantially rectangular, and the positions and shapes of the gate exposed portion 19, the drain exposed portion 20 and the source exposed portion 21 are line symmetrical with respect to the base line 54. In addition, the area of each source exposed portion 21 may be greater than the area of the gate exposed portion 19 and the area of the drain exposed portion 20. The source electrode 17 can be vertically divided into two parts of the source electrode 17 along the base line 54 located at the center in the vertical direction, and the source exposed portion 21 is formed on each part of the source electrode 17.

As shown in FIG. 3B, the gate exposed portion 19 and the drain exposed portion 20 are formed in a circular shape, and the source exposed portion 21 is formed in a rectangular shape, and the rectangular shape continues from near the upper end of the source electrode 17 to near the lower end of the source electrode 17. Even so, the position and shape of the source exposed portion 21 are still line symmetrical with respect to the base line 54.

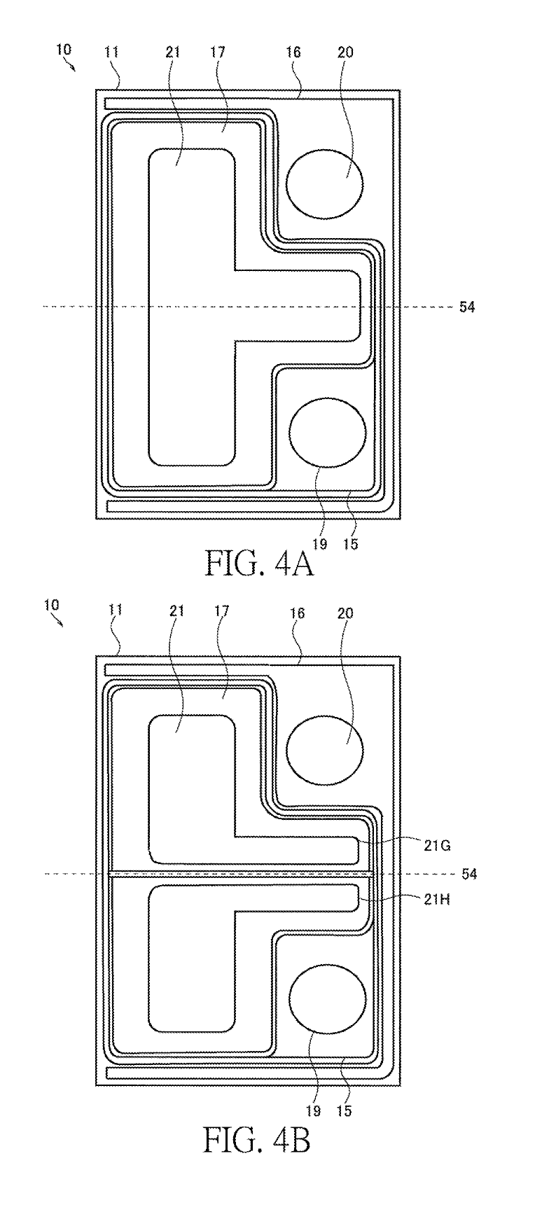

Please refer to FIG. 4A and FIG. 4B. FIG. 4A and FIG. 4B illustrate plan views of the semiconductor device in another embodiment of the invention. The structure of the semiconductor device 10 illustrated in FIG. 4A and FIG. 4B is basically the same as that of FIG. 1, and only the shapes of the exposed portions are different.

As shown in FIG. 4A, the source exposed portion 21 and the source electrode 17 have the same shape of protruding rightward on the paper surface. Even so, the position and shape of the source exposed portion 21 are still line symmetrical with respect to the base line 54.

As shown in FIG. 4B, the source exposed portion 21 in FIG. 4A can be divided into two partial source exposed portions 21G˜21H along the base line 54 located at the center in the vertical direction. Even so, the positions and shapes of the two partial source exposed portions 21G˜21H are still line symmetric with respect to the base line 54.

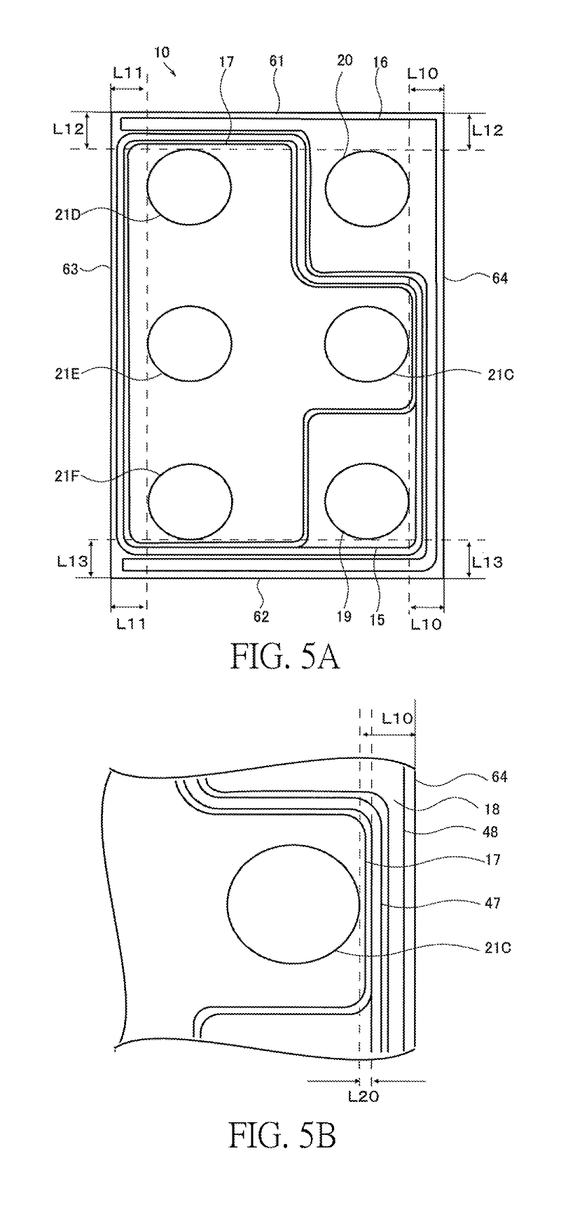

Please refer to FIG. 5A and FIG. 5B. FIG. 5A illustrates a plan view of the positions of the exposed portions of the semiconductor device 10, and FIG. FIG. 5B illustrates an enlarged plan view of the source exposed portion 21C in FIG. 5A.

As shown in FIG. 5A, source exposed portions 21C, 21D, 21E and 21F are formed on the source electrode 17. In this embodiment, in order to stably package the semiconductor device 10 on the package substrate through the solder, the exposed portions (e.g., the gate exposed portion 19, the drain exposed portion 20 and the source exposed portions 21C, 21D, 21E and 21F) will be disposed near the outside as much as possible. In addition, although the positions of exposed portions are determined based on the position of the source exposed part 21C, but not limited to this.

Specifically, the source exposed portion 21C is located on the part of the source electrode 17 protruding rightward on the paper surface. In other words, the source exposed portion 21C is located on the part of the source electrode 17 between the gate electrode 15 and the drain electrode 16. Since wiring portions are formed on the outside, the source exposed portion 21C is less likely to lead out to the outside. Therefore, in this embodiment, the source exposed portion 21C will be disposed as close as possible to the outside, and the positions of the other exposed portions will be relatively disposed based on the position of the source exposed portion 21C.

In detail, if the distance between the source exposed portion 21C and the right side 64 of the semiconductor substrate 11 is L10, then the distance between the gate exposed portion 19 and the right side 64 of the semiconductor substrate 11 and the distance between the exposed portions 20 and the right side 64 of the semiconductor substrate 11 are also L10. In addition, if the distance between the source exposed portion 21D and the upper side 61 of the semiconductor substrate 11 is L12, then the distance between the drain exposed portion 20 and the upper side 61 of the semiconductor substrate 11 will be also L12, and L12 is equal to L10. Furthermore, the distances between the left side 63 of the semiconductor substrate 11 and the source exposed portions 21D, 21E, 21F are all L11, and L11 is also equal to L10. In addition, the distance between the lower side 62 of the semiconductor substrate 11 and the source exposed portion 21F and the distance between the lower side 62 of the semiconductor substrate 11 and the gate exposed portion 19 are both L13, and L13 is also equal to L10.

As shown in FIG. 5B, the gate wiring 47 and the drain wiring 48 are pulled out on the right side of the source exposed portion 21C. The distance between the source exposed portion 21C and the right side 64 of the semiconductor substrate 11 is L10. During the packaging process, the length of the solder welded on the source exposed portion 21C will be shortened as much as possible without short-circuiting the gate wiring 47 and the drain wiring 48. For example, the distance L20 between the gate wiring 47 and the source exposed portion 21C can be set larger than the thickness of the cover insulation layer 18.

As mentioned above, after the short circuit when packaging is observed and the distance between the source exposed portion 21C and the right side 64 of the semiconductor substrate 11 is set to be L10, then the positions of the other exposed portions can be determined based on L10, so that all the exposed part will be uniformly disposed as close to the outside as possible. Therefore, in the subsequent reflow step, unexpected rotation or the like of the semiconductor device 10 can be avoided.

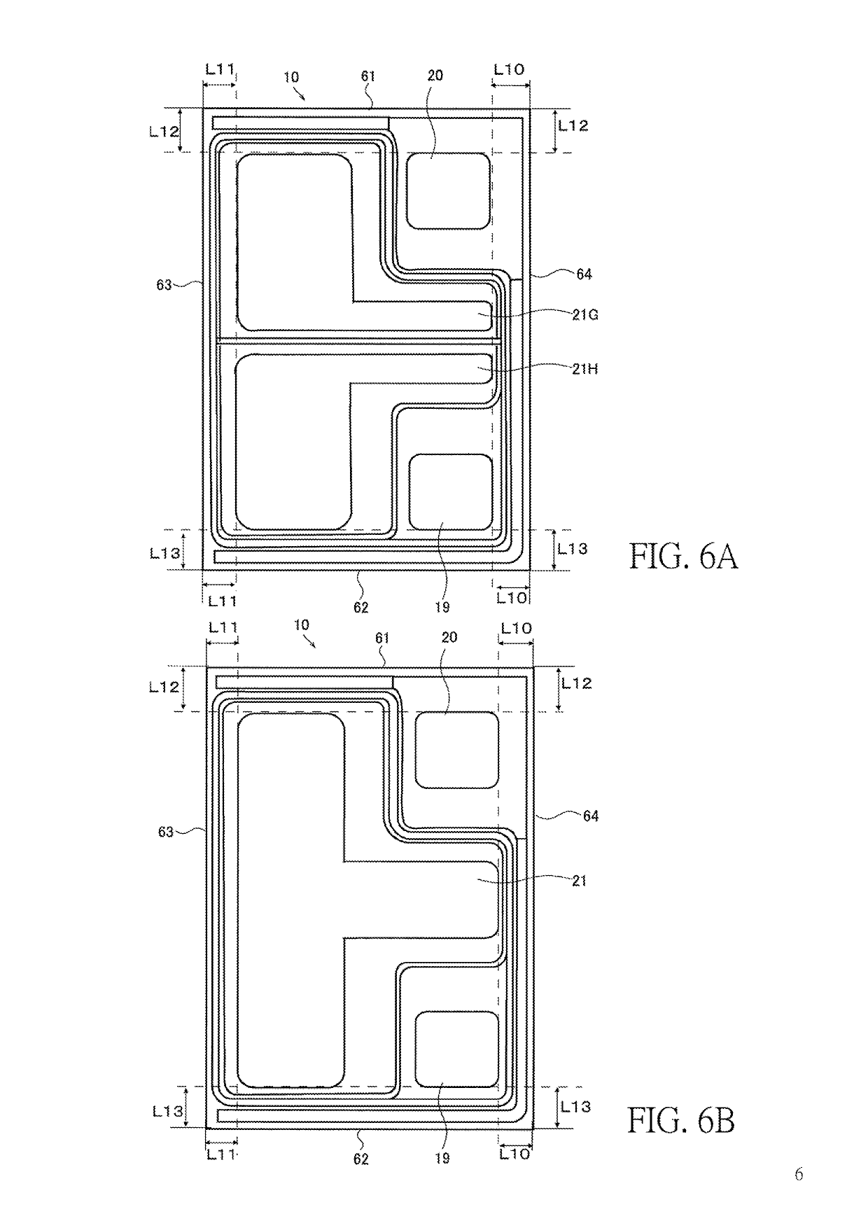

Please refer to FIG. 6A. FIG. 6A illustrates a modified embodiment of the semiconductor device 10 in FIG. 5A. The structure of the semiconductor device 10 in FIG. 6A is basically the same as that of FIG. 5 except that the shapes of the exposed portions are different. Specifically, the gate exposed portion 19 and the drain exposed portion 20 substantially have a rectangular shape. The source exposed portions 21G˜21H are vertically separated from each other and they partially extend rightward. If the distance between the right end of the source exposed portions 21G˜21H and the right side 64 of the semiconductor substrate 11 is L10, the distances between the other exposed portions and each side of the semiconductor substrate 11 are determined based on the distance L10. In this way, when the area of the source exposed portions 21G˜21H is increased, although the semiconductor device 10 is unstable because the amount of the solder used during the packaging process is increased, the semiconductor device 10 can become more stable during the packaging process by uniformly disposing all exposed portions as close to the outside as possible.

Please refer to FIG. 6B. The structure of the semiconductor device 10 in FIG. 6B is substantially the same as that of FIG. 6A, except that the source exposed portion 21 in FIG. 6B is not separated vertically. If the distance between the right end of the source exposed portion 21 and the right side 64 of the semiconductor substrate 11 is L10, and the distances between the other exposed portions and each side of the semiconductor substrate 11 are determined based on the distance L10, the aforementioned effects can be achieved.

What is claimed is:

1. A semiconductor device, comprising:
a semiconductor substrate having a first surface and a second surface opposite to each other, wherein a gate region, a drain region and a source region is formed on the semiconductor substrate;
a gate electrode, disposed on the first surface of the semiconductor substrate and coupled to the gate region;
a drain electrode, disposed on the first surface of the semiconductor substrate and coupled to the drain region;
a source electrode, disposed on the first surface of the semiconductor substrate and coupled to the source region, wherein an area of the source electrode is larger than an area of the gate electrode and an area of the drain electrode; and
a covering insulation layer, disposed on the first surface of the semiconductor substrate and at least partially covering the gate electrode, the drain electrode and the source electrode,
wherein a gate exposed portion of the gate electrode is exposed from the covering insulation layer; a source exposed portion of the source electrode is exposed from the covering insulation layer; a drain exposed portion of the drain electrode is exposed from the covering insulation layer; a part of the source electrode is disposed between the gate electrode and the drain electrode; the source exposed portion is disposed between the gate exposed portion and the drain exposed portion.

2. The semiconductor device of claim 1, wherein the gate exposed portion, the source exposed portion and the drain exposed portion are disposed relative to a side of the semiconductor substrate and the gate exposed portion, the source exposed portion and the drain exposed portion are line symmetrical with respect to a base line.

3. The semiconductor device of claim 2, wherein the source exposed portion is line symmetrical with respect to the base line.

4. The semiconductor device of claim 1, further comprising:
a wiring, coupled to the drain region or the gate region, wherein the part of the source electrode between the gate electrode and the drain electrode is disposed inside separated from the wiring, the part of the source electrode is separated from a side of the semiconductor substrate by a first distance, and another part of the source electrode, the drain exposed portion and the gate exposed portion are separated from the side of the semiconductor substrate by a second distance equal to the first distance.

5. The semiconductor device of claim 2, further comprising:
a wiring, coupled to the drain region or the gate region, wherein the part of the source electrode between the gate electrode and the drain electrode is disposed inside separated from the wiring, the part of the source electrode is separated from the side of the semiconductor substrate by a first distance, and another part of the source electrode, the drain exposed portion and the gate exposed portion are separated from the side of the semiconductor substrate by a second distance equal to the first distance.

6. The semiconductor device of claim 3, further comprising:
a wiring, coupled to the drain region or the gate region, wherein the part of the source electrode between the gate electrode and the drain electrode is disposed inside separated from the wiring, the part of the source electrode is separated from the side of the semiconductor substrate by a first distance, and another part of the source electrode, the drain exposed portion and the gate exposed portion are separated from the side of the semiconductor substrate by a second distance equal to the first distance.

7. The semiconductor device of claim 1, further comprising:
a gate wiring, disposed around the source electrode and coupled to the gate region and the gate electrode.

8. The semiconductor device of claim 2, further comprising:
a gate wiring, disposed around the source electrode and coupled to the gate region and the gate electrode.

9. The semiconductor device of claim 3, further comprising:
a gate wiring, disposed around the source electrode and coupled to the gate region and the gate electrode.

10. The semiconductor device of claim 4, further comprising:
a gate wiring, disposed around the source electrode and coupled to the gate region and the gate electrode.

11. A power conversion circuit, comprising:
a semiconductor device, comprising:
a semiconductor substrate having a first surface and a second surface opposite to each other, wherein a gate region, a drain region and a source region is formed on the semiconductor substrate;
a gate electrode, disposed on the first surface of the semiconductor substrate and coupled to the gate region;
a drain electrode, disposed on the first surface of the semiconductor substrate and coupled to the drain region;
a source electrode, disposed on the first surface of the semiconductor substrate and coupled to the source region, wherein an area of the source electrode is larger than an area of the gate electrode and an area of the drain electrode; and
a covering insulation layer, disposed on the first surface of the semiconductor substrate and at least partially covering the gate electrode, the drain electrode and the source electrode; and
a package substrate having a conductive path, wherein the semiconductor device is packaged on the conductive path.

12. The power conversion circuit of claim 11, wherein the gate exposed portion, the source exposed portion and the drain exposed portion are disposed relative to a side of the semiconductor substrate and the gate exposed portion, the source exposed portion and the drain exposed portion are line symmetrical with respect to a base line.

13. The power conversion circuit of claim 12, wherein the source exposed portion is line symmetrical with respect to the base line.

14. The power conversion circuit of claim 11, wherein the semiconductor device further comprises:
a wiring, coupled to the drain region or the gate region, wherein the part of the source electrode between the gate electrode and the drain electrode is disposed inside separated from the wiring, the part of the source electrode is separated from a side of the semiconductor substrate by a first distance, and another part of the source electrode, the drain exposed portion and the gate exposed portion are separated from the side of the semiconductor substrate by a second distance equal to the first distance.

15. The power conversion circuit of claim 12, wherein the semiconductor device further comprises:
a wiring, coupled to the drain region or the gate region, wherein the part of the source electrode between the gate electrode and the drain electrode is disposed inside separated from the wiring, the part of the source electrode is separated from the side of the semiconductor substrate by a first distance, and another part of the source electrode, the drain exposed portion and the gate exposed portion are separated from the side of the semiconductor substrate by a second distance equal to the first distance.

16. The power conversion circuit of claim 13, wherein the semiconductor device further comprises:
a wiring, coupled to the drain region or the gate region, wherein the part of the source electrode between the gate electrode and the drain electrode is disposed inside separated from the wiring, the part of the source electrode is separated from the side of the semiconductor substrate by a first distance, and another part of the source electrode, the drain exposed portion and the gate exposed portion are separated from the side of the semiconductor substrate by a second distance equal to the first distance.

17. The power conversion circuit of claim 11, wherein the semiconductor device further comprises:
a gate wiring, disposed around the source electrode and coupled to the gate region and the gate electrode.

18. The power conversion circuit of claim 12, wherein the semiconductor device further comprises:
a gate wiring, disposed around the source electrode and coupled to the gate region and the gate electrode.

19. The power conversion circuit of claim 13, wherein the semiconductor device further comprises:
a gate wiring, disposed around the source electrode and coupled to the gate region and the gate electrode.

20. The power conversion circuit of claim 14, wherein the semiconductor device further comprises:
a gate wiring, disposed around the source electrode and coupled to the gate region and the gate electrode.
